(19) United States
(12) Patent Application Publication
(10) Pub. No.: US 2022/0111807 A1
(43) Pub. Date: Apr. 14, 2022

(54) METHOD FOR MONITORING A CABLE HARNESS

(71) Applicants: Robert Bosch GmbH, Stuttgart (DE); AUDI AG, Ingolstadt (DE)

(72) Inventors: Rüdiger Velten, Illingen (DE); Axel Strommer, Brackenheim (DE); Juergen Motz, Steinheim An Der Murr (DE); Matthias Zabka, Suessen (DE); Quang-Minh Le, Hemmingen (DE); Sebastian Kaspar, Ingolstadt (DE); Patrick Lueckel, Stuttgart (DE); Daniel Rabl, Dietfurt (DE)

(21) Appl. No.: 17/450,022

(22) Filed: Oct. 5, 2021

(30) Foreign Application Priority Data
Oct. 13, 2020 (DE) 102020126921.8

(51) Int. Cl. B60R 16/02; G01R 31/66; B60W 50/14

(52) U.S. Cl. CPC B60R 16/0215; G01R 31/66; B60W 2710/20; B60W 2050/143; B60W 50/14

(57) ABSTRACT

A method for monitoring a cable harness. In the method, at least one value of at least one electrical variable in the cable harness is acquired and at least one signal, which represents this at least one value, is transmitted to at least one evaluator. A number of containers, which in turn represent a value range for the allocated electrical variable in each case, is allocated to each evaluator. The at least one signal is evaluated in such a way that the acquired values are allocated to the containers while taking the respective value range into account. The values allocated to the container are counted in each container. If a threshold value allocated to the container is exceeded, an action is triggered.

### CROSS REFERENCE

The present application claims the benefit under 35 U.S.C. § 119 of German Patent Application No. 102020126921.8 filed on Oct. 13, 2020, which is expressly incorporated herein by reference in its entirety.

### FIELD

The present invention relates to a method for monitoring a cable harness and to a system for carrying out the method.

### BACKGROUND INFORMATION

A cable harness is a bundling of individual lines that transmit signals or operating currents. The lines are routed in the form of a cable harness and encased or they are held together by clamps, cable ties, binding twine or tubes. Cable harnesses are regularly designed in accordance with the geometrical and electric requirements. The cable harness provides the lines for a vehicle electrical system.

A vehicle electrical system, which could also be called an energy supply network, in the automotive application is to be understood as the totality of electrical components in a motor vehicle. Thus, it encompasses both electrical consumers and supply sources such as batteries. In the motor vehicle, the availability of electrical energy is important so that the motor vehicle can be started up at all times and a sufficient current supply is available during the operation. In a parked state, too, electrical consumers should still be operable for an adequate period of time without any adverse effect on a subsequent starting operation.

Essential functions in modern vehicles, e.g., the steering system, brake systems and an environment sensor system, depend on a reliable electrical supply. In particular in the context of automated driving it is absolutely necessary to monitor the electrical supply of safety-relevant consumers and to ensure their function since the driver may possibly have no mechanical backup solutions available to avoid an emergency situation in the event of a system failure.

Against this background, a diagnosis of the vehicle electrical system and its components is required. German Patent Application No. DE 199 59 019 A1 describes a component-side diagnosis of an energy store such as a generator, an existing DC voltage converter or a battery via a battery sensor. The described method is used for detecting the state of the energy store, its actual variables being conveyed to an estimation routine. This ensures the function of the individual components.

Generally, vehicles having automated driving functions include a redundantly implemented onboard voltage network, to whose two channels the safety-relevant consumers are split up in order to provide an emergency operation in the event of a failure of one channel.

German Patent No. DE 197 55 050 C2 describes a redundant configuration of an onboard voltage network. This document describes a device for an energy supply in an onboard electrical system of a motor vehicle for at least two consumers of a similar type. In the device, one of the consumers of a similar type is connected to a voltage accumulator in each case, and the voltage accumulators are galvanically separated from each other.

In addition, the following solutions are conventional for the diagnosis of cable harness errors in the vehicle electrical system:

German Patent Application No. DE 10 2015 221 725 A1 describes a method for monitoring a vehicle electrical system, which has at least one channel that includes at least one component and an energy supply. In at least one channel, the at least one component measures a terminal voltage, which is compared with a voltage provided by the energy supply. On that basis, a transition resistance with respect to the component is calculated.

In addition, a method for monitoring an energy supply in a motor vehicle is described in German Patent Application No. DE 10 2018 212 369 A1. In this method, at least one energy store in a partial onboard electrical system supplies multiple consumers, e.g., safety-relevant consumers. At least one measured variable of an energy store and/or at least one consumer is/are acquired in the process. A cable harness model is provided, which maps the partial onboard electrical system. In addition, a parameter estimator is provided, which estimates at least one parameter with the aid of the measuring variable. It should be pointed out that an estimate of resistances in the supply cable harness is essentially carried out in the method.

### SUMMARY

In accordance with the present invention, a method and a system are provided. Example embodiments result from the disclosure herein.

The method in accordance with the present invention is used for monitoring a cable harness and may also be referred to as a method for monitoring an onboard electrical system realized by the cable harness.

The method in accordance with the present invention is used for monitoring a cable harness, and at least one value of at least one electrical variable in the cable harness is acquired in the method. This means that the electrical variable is measured, in particular multiple times, at a location in the cable harness and the values acquired during the measurement are further processed as described here. For example, the electrical resistance, the electrical voltage or the electric current intensity may be considered as electrical variables. For instance, if the electrical resistance is measured at three locations in the cable harness, then this means that values for three electrical variables are acquired.

At least one signal, which represents this at least one value, is then transmitted to at least one evaluator. A signal is typically generated for the values of every electrical variable. Also, an evaluator is then allocated to each electrical variable.

In accordance with an example embodiment of the present invention, a number of containers is in turn allocated to each evaluator, which in turn represents a value range for the allocated electrical variable in each case, typically restricted by an upper and a lower value. The at least one signal is evaluated in such a way that the acquired values are allocated to the containers while taking the respective value range into account. In this way the values are sorted into a kind of histogram.

The values allocated to the containers are counted in each container. If a threshold value allocated to the container is exceeded, an action is triggered. For instance, every value allocated to a container increases a counter which counts the values; put another way, each allocated value increments this counter.

When a threshold value allocated to the container is exceeded, an action is triggered. This means that at least one threshold value is allocated to each container, and threshold values that are allocated only to one container or to multiple containers are able to be specified. If multiple threshold values are allocated to a container, then it is also possible to trigger different actions as a function of the achieved threshold value.

It was recognized that conventional methods carry out only an estimate of resistances in the supply cable harness. In contrast, in accordance with the present invention, for the first time, a detailed method is provided for evaluating the acquired values or estimated values. A solution in this context is the use of a simple threshold value for ascertaining a cable harness error. A compromise must be found between a reliable detection and an avoidance of faulty diagnoses. Here, an approach is described that addresses and optimizes these aspects. The method may be based on a resistance estimator which generates the values for the evaluator.

The system in accordance with the present invention is set up to carry out the described method and is able to be implemented in hardware and/or software. In addition, the system is able to be integrated into a control unit of a motor vehicle or be embodied as such.

At least in some of the embodiments of the present invention, the introduced method and the described system make it possible to increase the vehicle availability through a robust detection of cable harness errors. To this end, filtering of discrete features is implemented for the diagnosis, e.g., via a histogram. The sensitivity of the error qualification or filtering is a function of the magnitude of the feature based on a trigger threshold that is able to be configured per container or bin. Different warning stages may furthermore be provided depending on the state of age (error manifestation) of the cable harness.

Additional advantages and embodiments of the present invention result from the description herein and the figures.

It is of course understood that the above-mentioned features and the features still to be described are able to be used not only in the respectively indicated combination but also in other combinations or on their own without departing from the scope of the present invention.

### BRIEF DESCRIPTION OF THE DRAWINGS

FIG. 1 shows a vehicle electrical system.

FIG. 2 shows the transmission of data.

FIG. 3 shows a possible sequence of the described method in a flow diagram in accordance with an example embodiment of the present invention.

FIG. 4 shows the procedure when executing the described method, based on a diagram, in accordance with an example embodiment of the present invention.

FIG. 5 shows a schematic representation of a system for carrying out the present method, in accordance with an example embodiment of the present invention.

### DETAILED DESCRIPTION OF EXAMPLE EMBODIMENTS

The present invention is schematically illustrated in the figures based on embodiments and will be described in detail in the following text with reference to the figures.

Hereinafter, the focus is predominantly on resistances as variables to be acquired in the cable harness. This is done merely by way of example. The present invention is not restricted to such a development and the electric voltage, the electric current intensity and/or the electrical resistance but naturally also other electrical variables are able to be acquired as electrical variables.

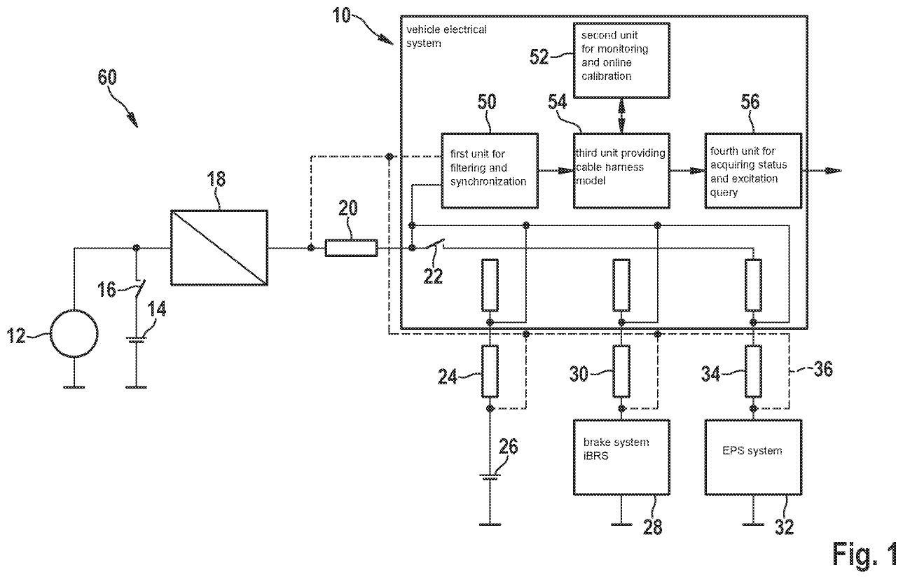

FIG. 1 shows an exemplary vehicle electrical system, which has been denoted by reference numeral 10 as a whole and whose basic structure is shown there. This vehicle electrical system 10 includes an electric machine 12, a high-voltage battery BHV 14 having an allocated switch 16 and a DC-voltage converter 18. In addition, the illustration shows a resistance R_{DC2} 20, a further switch 22, a resistance R_{B} 24, a battery B 26, a brake system iBRS 28 as a respective safety-relevant consumer with allocated cable harness resistance R_{iBRS} 30, an EPS system 32 as a safety-relevant consumer with an allocated cable harness resistance R_{EPS} 34, and a CAN bus 36, which is illustrated by a dashed line.

A cable harness diagnosis 40 is indicated by a border; here, a first unit 50 for filtering and a synchronization, a second unit 52 for monitoring and an online calibration, a third unit 54 for providing a cable harness model, and a fourth unit 56 for acquiring the status as well as an excitation query are provided.

A sketched high-voltage vehicle electrical system 60, which in this case includes electrical machine 12, high-voltage battery B_{HV} 14 used as a traction battery, and a switch 16, will not be addressed here in greater detail. It should be noted that the monitored and involved components may differ depending on the vehicle. For instance, a generator, a starter and other safety-relevant consumers may be provided.

It is assumed that a diagnosis function, which ascertains one or more partial cable harness resistance(s), is carried out in vehicle electrical system 10.

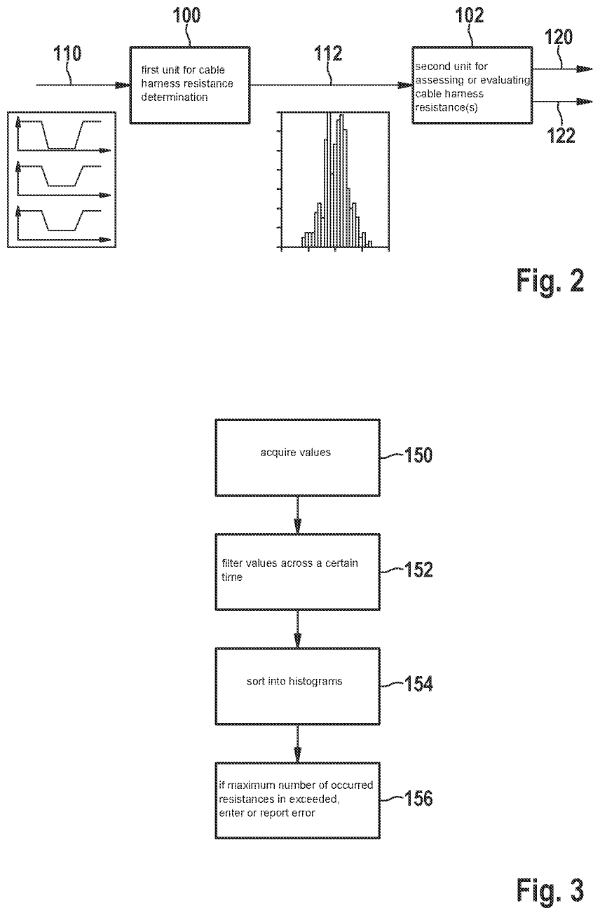

The ascertained discrete resistance values—resistances or consumers R_{DC2} 20, R_{B} 24, R_{iBRS} 30 and R_{EPS} 34 in the illustration—are evaluated separately for each cable harness channel in an evaluation unit described in the following text, i.e. the introduced system, and an item of error information is ascertained therefrom. In addition, if resistance information is missing—the resistance determination can take place only if a current is flowing in the respective cable harness branch—a request for the generation of a current excitation is generated. Reference is made to the diagram illustrated in FIG. 2 in this context.

FIG. 2 shows a first unit 100 for a cable harness resistance determination and a second unit 102 for assessing or evaluating the cable harness resistance(s).

First unit 100 thus is used for determining the partial cable harness resistance, and the further evaluation, which is addressed here in particular, is assumed by second unit 102.

Input variables for the first unit are voltage U and current I across an input 110, and an output variable at an output 112 is the cable harness resistance which is entered into second unit 102, at whose first output 120 a status regarding the cable harness is output and at whose second output an excitation query is output.

The following has to be taken into account in connection with the excitation query. If it is impossible to estimate a resistance because there is no current excitation, then there exists the possibility of posing a query via CAN to the steering system (EPS) and to generate a current pulse. The current pulse may then be used for estimating a resistance.

In first unit 100, a data fusion, a synchronization of the voltage and current data as well as an estimate of the cable harness resistance take place. In second unit 102, an evaluation of the cable harness resistance, a generation of an error status and a generation of the excitation query are carried out in case of an insufficient current excitation in order to perform a determination of the cable harness resistance.

Random deviations of the ascertained values may occur when ascertaining the cable harness resistances due to interference in the vehicle electrical system, latencies in the communication and temperature effects. Here, a reliable and robust diagnosis has to provide adequate filtering so that a false positive/false negative error classification is avoided.

To this end, in one embodiment according to FIG. 3, the introduced method provides for an acquisition of values in a first step 150 and for simple filtering of the values across a certain time in a second step 152. This may be accomplished via moving average filtering of a certain number of resistance values, an averaging across a certain time or during a driving cycle.

It may also be useful to carry out root mean squaring in order to evaluate upward outliers to a greater degree. In third step 154, the value prefiltered in this way is then sorted into a histogram whose ranges may be subdivided as desired, asymmetrically. In the illustrated example, six resistance ranges are defined into which the ascertained resistance value of the partial cable harness is divided, as indicated by the following table:

| Range | Description |
|---|---|
| too low | Implausibly low resistance |
| R < R_too lowMax | |
| ok | Resistance within the normal range |
| R_too low < R_okRangeMax | |
| aged | Increased resistance. Ageing is |
| R_okRangeMax < R < R agedMax | present. Supply lines should be |
| | checked during the next service |
| | visit |
| yellow | Resistance greatly increased, |
| R_agedMax < R < R_yellowMax | Message request to driver to |
| | visit a service center |
| red | Resistance critical, message to |
| R_yellowMax < R < R_redMax | driver that vehicle must be |
| | stopped immediately |
| Safety limit | Safety limit for supply path R > |
| R_redMax | violated, vehicle must be |
| | transferred to safe state |
| | immediately. |

The resistance ranges correspond to a container in each case. The containers, which in turn are allocated to an electrical variable, i.e., in this case the electrical resistance whose values are acquired, form what is called an evaluator.

The number of resistance values that have occurred for each container is stored in a non-volatile memory, for instance, and updated across the service life of the vehicle. If a maximum number of occurred resistances is exceeded in the corresponding container, then the particular range is considered to be successfully classified, and the corresponding error is entered or reported. This takes place in a step 156.

Since individual outliers in the resistance value may occur despite the prefiltering, it is useful to empty the containers, which are also known as histogram bins or only bins, following a certain time because it may otherwise happen after long operating intervals that the outliers add up in such a way that an error diagnosis occurs. There are various possibilities for accomplishing this. In the simplest case, the described system decrements all containers that are not empty at fixed time intervals or after a certain number of driving cycles. A certain occurrence frequency of an error class must therefore be given before an error is classified.

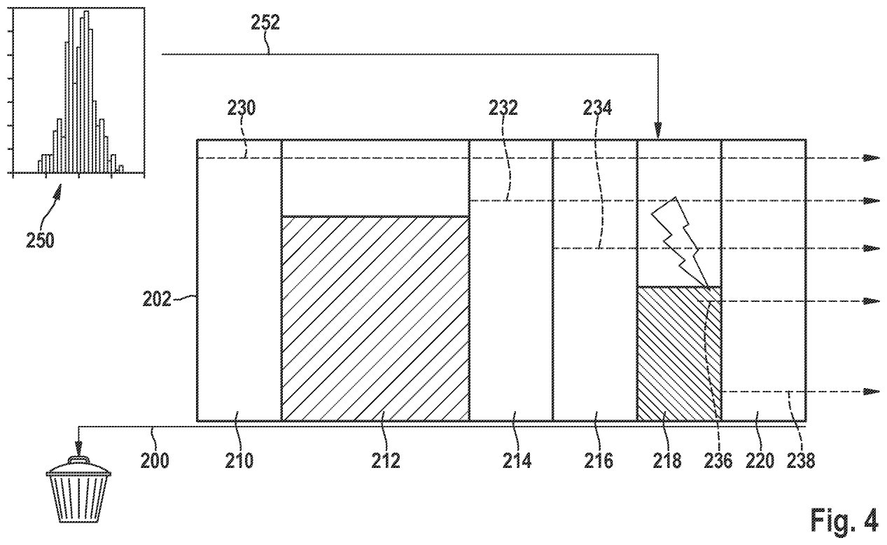

The example method is shown in the following diagram of FIG. 4. Resistance values which define the value ranges of the containers are shown along a first axis 200 and a counter reading is shown along a second axis 202. Six ranges or containers, which are also listed in table 1, are identified in the illustration, i.e.:

| | |
|---|---|
| 1. Range 210 | too low |
| 2. Range 212 | OK |
| 3. Range 214 | aged |
| 4. Range 216 | yellow |
| 5. Range 218 | red |
| 6. Range 220 | beyond the safety limit |

Threshold values are allocated to the ranges, that is to say, a first threshold value 230, a second threshold value 232, a third threshold value 234, a fourth threshold value 236, and a fifth threshold value 238.

Allocated to first threshold value 230 is the information “Threshold value is implausible, too low”, the information “aged” is allocated to second threshold value 232, “aged, driver warning yellow” is allocated to third threshold value 234, “aged, driver warning red” is allocated to fourth threshold value 236, and “aged, immediate drive train degradation” is allocated to fifth threshold value 238.

The illustration furthermore shows a graph 250, which illustrates a statistical evaluation of the measuring results. Via a signal line 252, accumulated resistance values are transmitted during the driving cycle, which are sorted into the containers.

An exception with regard to the filtering is the “safety limit” error class. Here, no prefiltering is carried out and only one occurrence is required to classify the error. Since a direct violation of the safety targets is given here, an immediate reaction is required for safety reasons.

Another part of the system monitors the actuality of the ascertained resistance values. The availability for use of the vehicle depends on whether the required test intervals of the vehicle cable harness were observed. If no reliable value is available for a longer period of time, then no reliable statement about the operativeness is able to be made.

The following measures are taken when no current cable harness resistance is available:

Step 1: Request to the vehicle to generate a load pulse.

Step 2: If the request is unsuccessful, generate a driver report.

Here, it may be useful to repeat the requests across multiple driving cycles or over a certain period of time before an error is ultimately reported.

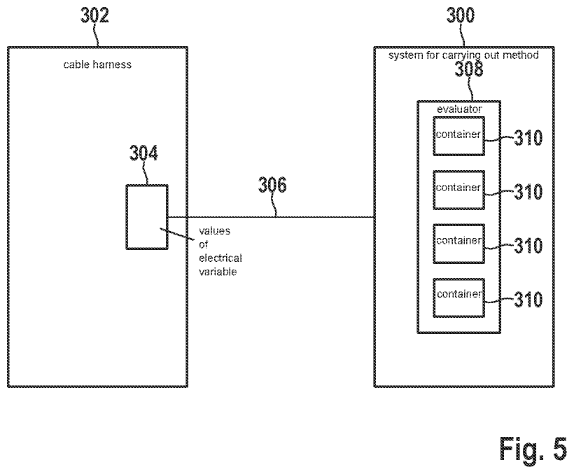

FIG. 5 shows in a purely schematic representation a system for carrying out the method, which is denoted by reference numeral 300 as a whole. This system is used to monitor a cable harness 302 in which values for an electrical variable 304 are acquired. A signal 306 that represents these values is then transmitted to system 300 and evaluated there. The values of this electrical variable 304 are assigned to an evaluator 308, and the values are sorted into containers 310, which in turn are defined by value ranges.

What is claimed is:

1. A method for monitoring a cable harness, the method comprising the following steps:
acquiring values of at least one electrical variable in the cable harness;
transmitting to at least one evaluator at least one signal which represents the acquired values;
allocating a number of containers, which each represents a respective value range for the electrical variable;
evaluating the at least one signal is evaluated in such a way that the acquired values are allocated to the containers while taking the respective value range into account;
counting the values allocated to the containers in each of the containers; and
based on exceeding a threshold value allocated to a container of the containers, triggering an action.

2. The method as recited in claim 1, wherein filtering of the values is performed before the values are allocated to the corresponding container.

3. The method as recited in claim 2, in which the filtering includes a measure that is selected from a group that includes: (i) forming a moving average of a certain number of values, (ii) averaging across a certain time or during a driving cycle, (iii) root mean squaring.

4. The method as recited in claim 1, wherein the at least one electrical variable is a variable that is selected from a group that includes: (i) an electrical resistance, (ii) an electrical voltage, (iii) an electrical current intensity.

5. The method as recited in claim 1, wherein the containers are emptied as a function of events.

6. The method as recited in claim 5, in which each of the containers is emptied following fixed time intervals or following a certain number of driving cycles.

7. The method as recited in claim 1, wherein the action is at least one measure selected from a group that includes: (i) a warning report to a driver, (ii) a request to the driver, (iii) transferring the vehicle to a safe state, (iv) an entry in an error memory, (v) a degradation of components, (vi) a reduction of a maximum steering moment.

8. The method as recited in claim 7, wherein the action is selected as a function of an ageing state of the cable harness.

9. A system for monitoring a cable harness, the system configured to:
acquire values of at least one electrical variable in the cable harness;
transmit to at least one evaluator at least one signal which represents the acquired values;
allocate a number of containers, which each represents a respective value range for the electrical variable;
evaluate the at least one signal is evaluated in such a way that the acquired values are allocated to the containers while taking the respective value range into account;
count the values allocated to the containers in each of the containers; and
based on exceeding a threshold value allocated to a container of the containers, triggering an action.
